(19) United States
(12) Patent Application Publication
(10) Pub. No.: US 2025/0118611 A1
(43) Pub. Date: Apr. 10, 2025

(54) ELECTRONIC PACKAGE ASSEMBLY AND A METHOD FOR FORMING THE SAME

(71) Applicant: STATS ChipPAC Pte. Ltd, Singapore (SG)

(72) Inventors: NamGu KIM, Incheon (KR); GyeongMin KIM, Incheon (KR); JeongHyun KIM, Busan (KR); HeunSu KIM, Busan (KR)

(21) Appl. No.: 18/900,913

(22) Filed: Sep. 30, 2024

(30) Foreign Application Priority Data
Oct. 8, 2023 (CN) 202311289483.7

(51) Int. Cl. H01L 23/31; H01L 21/56; H01L 23/498; H01L 23/60

(52) U.S. Cl. CPC H01L 23/3157; H01L 21/565; H01L 23/49816; H01L 23/60

(57) ABSTRACT

An electronic package assembly and a method for forming the same is provided. The electronic package assembly comprises: a first electronic package comprising a first package substrate, and a first mold cap formed on the first package substrate, wherein the first mold cap has at its periphery a male gap; and a second electronic package comprising a second package substrate, and a second mold cap formed on the second package substrate, wherein the second mold cap has at its periphery a female gap which mates the male gap in shape; wherein the first mold cap is connected with the second mold cap through an adhesive material with the male gap of the first mold cap being adjacent to the female gap of the second mold cap.

### TECHNICAL FIELD

The present application generally relates to semiconductor technology, and more particularly, to an electronic package assembly and a method for forming the same.

### BACKGROUND OF THE INVENTION

The semiconductor industry is constantly faced with complex integration challenges as consumers want their electronics to be smaller, faster and higher performance with more and more functionalities packed into a single device. In recent years, electronic packages are fabricated into smaller sizes to bring about higher density of electronic components. However, due to the complexity of IC design and limitations of fabrication processes, the space arrangement among semiconductor packages and electronic components mounted therein still remain to be improved, thus bringing about obstacles to the miniaturization of the electronic packages.

Therefore, a need exists for an electronic package with better space arrangement.

### SUMMARY OF THE INVENTION

An objective of the present application is to provide an electronic package assembly and a method for forming the same.

According to an aspect of embodiments of the present application, an electronic package assembly is provided. The electronic package assembly comprises: a first electronic package comprising a first package substrate, and a first mold cap formed on the first package substrate, wherein the first mold cap has at its periphery a male gap; and a second electronic package comprising a second package substrate, and a second mold cap formed on the second package substrate, wherein the second mold cap has at its periphery a female gap which mates the male gap in shape; wherein the first mold cap is connected with the second mold cap through an adhesive material with the male gap of the first mold cap being adjacent to the female gap of the second mold cap.

According to another aspect of the present application, a method for forming an electronic package assembly is provided. The method comprise: providing a first electronic package comprising a first package substrate, and a first mold cap formed on the first package substrate, wherein the first mold cap has at its periphery a male gap; providing a second electronic package comprising a second package substrate, and a second mold cap formed on the second package substrate, wherein the second mold cap has at its periphery a female gap which mates the male gap in shape; and connecting the first mold cap with the second mold cap through an adhesive material such that the male gap of the first mold cap is adjacent to the female gap of the second mold cap.

It is to be understood that both the foregoing general description and the following detailed description are exemplary and explanatory only, and are not restrictive of the invention. Further, the accompanying drawings, which are incorporated in and constitute a part of this specification, illustrate embodiments of the invention and together with the description, serve to explain the principles of the invention.

### BRIEF DESCRIPTION OF DRAWINGS

The drawings referenced herein form a part of the specification. Features shown in the drawing illustrate only some embodiments of the application, and not of all embodiments of the application, unless the detailed description explicitly indicates otherwise, and readers of the specification should not make implications to the contrary.

FIG. 1 illustrates a cross-sectional view of an electronic package assembly 100 according to a first embodiment of the present application.

FIG. 2 illustrates a top view of an electronic package assembly 200 according to a second embodiment of the present application.

FIG. 3 illustrates a cross-sectional view of an electronic package assembly 300 according to a third embodiment of the present application.

FIGS. 4A to 4G illustrate various steps of a method for making an electronic package assembly according to an embodiment of the present application.

The same reference numbers will be used throughout the drawings to refer to the same or like parts.

### DETAILED DESCRIPTION OF THE INVENTION

The following detailed description of exemplary embodiments of the application refers to the accompanying drawings that form a part of the description. The drawings illustrate specific exemplary embodiments in which the application may be practiced. The detailed description, including the drawings, describes these embodiments in sufficient detail to enable those skilled in the art to practice the application. Those skilled in the art may further utilize other embodiments of the application, and make logical, mechanical, and other changes without departing from the spirit or scope of the application. Readers of the following detailed description should, therefore, not interpret the description in a limiting sense, and only the appended claims define the scope of the embodiment of the application.

In this application, the use of the singular includes the plural unless specifically stated otherwise. In this application, the use of “or” means “and/or” unless stated otherwise. Furthermore, the use of the term “including” as well as other forms such as “includes” and “included” is not limiting. In addition, terms such as “element” or “component” encompass both elements and components including one unit, and elements and components that include more than one subunit, unless specifically stated otherwise. Additionally, the section headings used herein are for organizational purposes only, and are not to be construed as limiting the subject matter described.

As used herein, spatially relative terms, such as “beneath”, “below”, “above”, “over”, “on”, “upper”, “lower”, “left”, “right”, “vertical”, “horizontal”, “side” and the like, may be used herein for ease of description to describe one element or feature's relationship to another element(s) or feature(s) as illustrated in the Figures. The spatially relative terms are intended to encompass different orientations of the device in use or operation in addition to the orientation depicted in the Figures. The device may be otherwise oriented (rotated 90 degrees or at other orientations) and the spatially relative descriptors used herein may likewise be interpreted accordingly. It should be understood that when an element is referred to as being “connected to” or “coupled to” another element, it may be directly connected to or coupled to the other element, or intervening elements may be present.

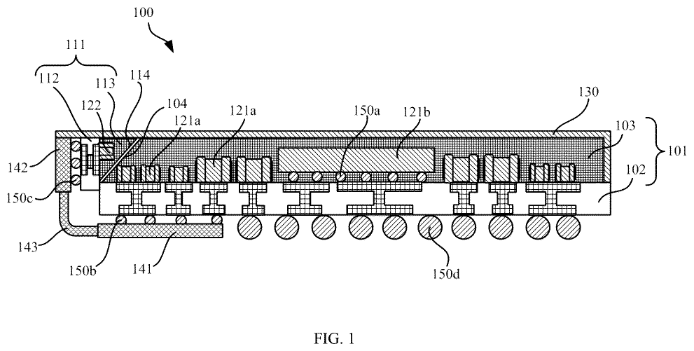

FIG. 1 illustrates a cross-sectional view of an electronic package assembly 100 according to a first embodiment of the present application. The electronic package assembly 100 may include various electronic components and substrates for mounting such electronic components.

As shown in FIG. 1, the electronic package assembly 100 includes a first electronic package 101, which further includes a first package substrate 102 and a first mold cap 103 formed on the first package substrate 102. Various electronic components may be mounted on the first package substrate 102 and encapsulated by the first mold cap 103. In the embodiment, the first mold cap 103 has at its periphery a male gap, which removes a portion of the first mold cap 103 but may not expose any of the electronic components.

The electronic package assembly 100 further includes a second electronic package 111, which further includes a second package substrate 112 and a second mold cap 113 formed on the second package substrate 112. Similar as the first mold cap 103, the second mold cap 113 also has at its periphery a female gap. The female gap may mate the male gap of the first mold cap 103 in shape, to allow for attachment of the second mold cap 113 onto the first mold cap 103. In this embodiment, the second electronic package 111 is substantially aligned with the male gap of the first mold cap 103, such that it can be mounted onto the first electronic package 101, or particularly the first mold cap 103 can be connected with the second mold cap 113 through an adhesive material. When the first and second electronic packages 101 and 111 are connected together, the male gap of the first mold cap 103 is adjacent to the female gap of the second mold cap 113.

In some embodiments, the first electronic package 101 may have a bigger form factor such that it can serve as a primary module in the whole electronic package assembly 100, and the second electronic package 111 may have a smaller form factor such that it can serve as an auxiliary module which functionally coordinates with the first electronic package 101 and may not be packaged with the second electronic package 111. For example, the first electronic package 101 may include electronic components such as signal processing component, power supply component or the like, which may have a bigger size, while the second electronic package 111 may include antennas or image sensors that may have a smaller size. However, it can be appreciated that various other types of electronic components may be mounted in either of the first and second electronic packages 101 and 111.

In the embodiment shown in FIG. 1, the first electronic package 101 further includes at least one first electronic component 121a mounted on the first package substrate 102. One or more of the first electronic components 121a may be close to the male gap, and disposed between the male gap and the first package substrate 102. Furthermore, the second electronic package 111 further includes at least one second electronic component 122 mounted on the second package substrate 112. One or more of the second electronic components 122 may be close to the female gap, and disposed between the female gap and the second package substrate 112. In some embodiments, the first electronic components 121a may include electronic components such as resistors or capacitors which may be small in size. The second electronic components 122 may be similarly small in size, for example, may be antennas. Thus, although mold materials are removed respectively at the male gap and the female gap, the smaller first electronic component 121a and second electronic component 122 can be fully encapsulated by the respective mold materials of the first mold cap 103 and second mold cap 113, and thus protected from the environment.

In the embodiment, the first electronic package 101 further includes at least one third electronic component 121b mounted on the first package substrate 102. In the embodiment shown in FIG. 1, the third electronic component 121b is away from the male gap, i.e., not between the male gap and the first package substrate 102. In some embodiments, the first electronic components 121a and the third electronic component 121b may be disposed randomly on the first package substrate 102. For example, in some cases, the third electronic component 121b may be disposed on a central region of the first package substrate 102, and in some other cases, it can be appreciated that the third electronic component 121b may be disposed on other regions of the first package substrate 102.

Furthermore, the third electronic component 121b is electrically connected with interconnect wires embedded in the first package substrate 102 via a plurality of solder bumps 150a. The conductive bump material can be Al, Sn, Ni, Au, Ag, lead (Pb), bismuth (Bi), Cu, or combinations thereof, with an optional flux solution. Similarly, the first and second electronic components 121a and 122 may be mounted on the first and second package substrates 102 and 112 respectively through solder bumps, for example.

The at least one third electronic component 121b may have a height greater than that of the first electronic component 121a. In some other embodiments, the positions and sizes of the third electronic component 121b and first electronic component 121a may vary according to actual needs of devices. For example, the third electronic component 121b may be attached close to an edge of the first package substrate 102 where no second electronic package is attached. In this embodiment, the third electronic components 121b may include electronic components such as semiconductor chips or other key functional modules. The third electronic components 121b and the first electronic components 121a, which are connected together through the interconnect wires embedded within the first package substrate 102, together serve as the main functional electronics within the whole electronic package assembly 100. Similarly, the second electronic components 122 may include electronic components such as resistors, capacitors or antennas, serving as the coupling electronics which functionally coordinate with the third electronic components 121b and the first electronic components 121a on the first package substrate 102. In some embodiments, the electronics on the first package substrate 102 may not be electrically coupled to the electronics on the second package substrate 112, while in some other embodiments, the electronics on the first package substrate 102 may be electrically coupled to the electronics on the second package substrate 112, which will be elaborated below.

As shown in FIG. 1, the first electronic component 121a may also have different heights, to be more specific, the first electronic component 121a that is mounted closer to the periphery of the first package substrate 102 may have a height smaller than that of the first electronic component 121a mounted relatively away from the periphery of the first package substrate 102, thus resulting in a descending trend in the heights of the electronic components from the third electronic component 121b to the first electronic components 121a on regions closer to the periphery of the first package substrate 102. In some other embodiments, at least one third electronic component 121b may have a greater height than that of the first electronic components 121a, while the first electronic components 121a may have the same height or may even have irregular and different heights according to various layouts of the first electronic package 101. Nevertheless, due to the smaller heights of the electronic components at or close to the periphery of the first electronic package 101, more space filled with the mold material is formed above the first electronic components 121a, compared with the space above the third electronic components 121b.

The first mold cap 103 formed on the first package substrate 102 covers respective front surfaces of the first electronic components 121a and the third electronic component 121b, and a front surface of the first package substrate 102 not mounted with the electronic components. The first mold cap 103 is used to protect the first electronic components 121a and the third electronic component 121b from any potential contamination during the subsequent fabrication or testing procedure, thus ensuring better electrical performance and reliability. The first mold cap 103 material includes polymer such as epoxy, polyimide, acrylic resin, and ceramic such as aluminum oxide, aluminum nitride, etc. Similarly, the second mold cap 113 formed on the second package substrate 112 covers a front surface of the second electronic component 122 and a front surface of the second package substrate 112 not mounted with the second electronic component 122.

In the embodiment shown in FIG. 1, the first electronic package 101 is placed adjacent to the second electronic package 111, and the male gap of the first mold cap 103 matches up with the female gap of the second mold cap 113 to ensure the coordinated placement of the first electronic package 101 and the second electronic package 111. To be more specific, for the first electronic package 101, due to the descending trend in the heights of the electronic components from the third electronic component 121b to the first electronic components 121a on regions closer to the periphery of the first package substrate 102, more space above the first electronic components 121a at the periphery of the first package substrate 102 is left unused. Such space, i.e., the male gap, can be used for the placement or attachment of the second electronic package 111 instead of the mold material. In some embodiments, the male gap of the first mold cap 103 includes a first chamfer 104 which also has an accordingly descending trend in the height direction of the first electronic package 101. As mentioned above, this shape of the male gap saves undesired mold materials above the first electronic components 121a mounted on regions closer to the periphery of the first package substrate 102 since the height of the first electronic components 121a there is smaller than that of the third electronic component 121b mounted on the region away from the periphery of the first package substrate 102. Also, it is simple to form such chamfered shaped gap.

Accordingly, the female gap of the second mold cap 113 may include a second chamfer 114. The second chamfer 114 may have a surface that is substantially identical to that of the first chamfer 104 of the first mold cap 103 so that they can be connected with each other well. In some embodiments, the first chamfer 104 may have a first angle relative to the first package substrate 102, the second chamfer 114 may have a second angle relative to the second package substrate 112, and a total of the first and second angles may be 90 degrees. As such, when attached together, the first package substrate 102 is perpendicular to the second package substrate 112. However, it can be appreciated that other shaped male and female gaps may be formed for the first and second mold caps. For example, the first chamfer 104 may have a first angle relative to the first package substrate 102 and the second chamfer 114 may have a second angle relative to the second package substrate 112. A total of the first and second angles may be 90 degrees, and the first angle is smaller than the second angle, such that the first electronic components 121a which are closer to the male gap of the first mold cap 103 may have heights smaller than that of the second electronic components 122. In some other embodiments, the first angle is greater than the second angle, such that the first electronic components which are closer to the male gap of the first mold cap may have heights greater than that of the second electronic components.

Furthermore, in some embodiments, the first mold cap 103 and the second mold cap 113 may form together a flat top surface where additional structures of the electronic package assembly 100 may be formed. For example, a shielding layer 130 may be formed at least on the flat top surface above the first and second mold caps 103 and 113, which may help to protect the other parts of the electronic package assembly 100 from electromagnetic interferences. In some examples, the shielding layer 130 may extend to the structures adjacent to the mold caps, and/or other surfaces (e.g., lateral surfaces) of the mold caps. The first mold cap 103 can be connected with the second mold cap 113 through an adhesive material, such that the male gap of the first mold cap 103 is adjacent to the female gap of the second mold cap 113. In the embodiment shown in FIG. 1, the adhesive material includes non-conducting materials. In some other embodiments, the first mold cap and the second mold cap may have conductive pillars embedded therein, and the adhesive material may include conducting tapes such as anisotropic conductive films, thus allowing for additional electrical paths between the first electronic components and the second electronic components. This assembly of the first electronic package 101 and the second electronic package 111 best utilizes the redundant space above the first electronic component 121a to accommodate the second electronic components 122, thus resulting in improved electronics density and integration level.

It can be appreciated that the embodiment shown in FIG. 1 is only a cross section of the electronic package assembly 100, and the electronic package assembly 100 may have other profiles or cross sections at other positions not shown in FIG. 1. In some other embodiments, the male gap of the first mold cap and the female gap of the second mold cap may include other shapes and arrangements. For example, in an alternative embodiment, the male gap of the first mold cap may include a first stepwise periphery according to different heights of the third electronic component and the first electronic component. Accordingly, the female gap of the second mold cap may include a second stepwise periphery which matches up with the first stepwise periphery. The first stepwise periphery and the second stepwise periphery can be set at the periphery of the first mold cap and the second mold cap, similar as the embodiment shown in FIG. 1. In some embodiments, the first stepwise periphery and the second stepwise periphery can also be set anywhere surrounding the third electronic component.

The first package substrate 102 and the second package substrate 112 can be made of flexible materials such as polymer, both with interconnect wires embedded therein. The first electronic components 121a mounted on the first package substrate 102 are electrically connected with the interconnect wires within the first package substrate 102, and the second electronic component(s) 122 mounted on the second package substrate 112 are electrically connected with the interconnect wires within the second package substrate 112. In some embodiments, the electronic components on the first and second package substrates 102 and 112 may not be electrically coupled with each other, but in some other embodiments, these electronic components may be electrically coupled with each other, as elaborated below.

As shown in FIG. 1, the electronic package assembly 100 further includes a first linkage substrate 141 which is mounted on a back surface of the first package substrate 102 and away from the first mold cap 103, through solder bumps 150b, for example. That is, the first linkage substrate 141 and the first mold cap 103 may be formed on two opposite sides of the first package substrate 102. Furthermore, in some embodiments, the first linkage substrate 141 may extend along a portion of the back surface of the first package substrate 102, rather than across an entire length or width of the back surface of the first package substrate 102. As such, a portion of the solder bumps 150d may be not covered by the first linkage substrate 141 and thus may be used for attaching and electrically connecting the first package substrate 102 with a base substrate or device where the entire electronic package assembly 100 is mounted. In some alternative embodiments, the first linkage substrate 141 may extend across the first package substrate 102 in at least one of a lengthwise direction and a widthwise direction of the first package substrate 102.

Furthermore, a second linkage substrate 142 may be mounted on a back surface of the second package substrate 112 and away from the second mold cap 113, through solder bumps 150c. That is, the second linkage substrate 142 and the second mold cap 113 may be formed on two opposite sides of the second package substrate 112. The first and second linkage substrates 141 and 142 may be connected with each other via a flexible link 143, which may have built-in electrical wires for electrically coupling the first and second linkage substrate 141 and 142 or may not have such wires. In some embodiments, the first linkage substrate 141, the second linkage substrate 142, and the flexible link 143 may be polymer tapes or sheets with interconnect wires embedded therein or coated thereon. In this way, the third electronic component 121b and the first electronic components 121a mounted on the first package substrate 102 and the second electronic component 122 mounted on the second package substrate 112 can be electrically connected with each other, forming an integrated electronic device.

In some embodiment, a length of the second electronic component 122 is smaller than a length of the first electronic component 121a, and thus a length of the second mold cap 113 covering the second electronic component 122 is also smaller than a length of the first mold cap 103. Accordingly, the male gap may not extend across a width of the first mold cap 103, i.e., occupy a corner of the first mold cap 103. In some other embodiments, the first electronic component 121a and the second electronic component 122, as well as the first mold cap 103 and the second mold cap 113, can be sized and arranged according to actual needs of the electronic package assembly, as long as no interference may occur between these components.

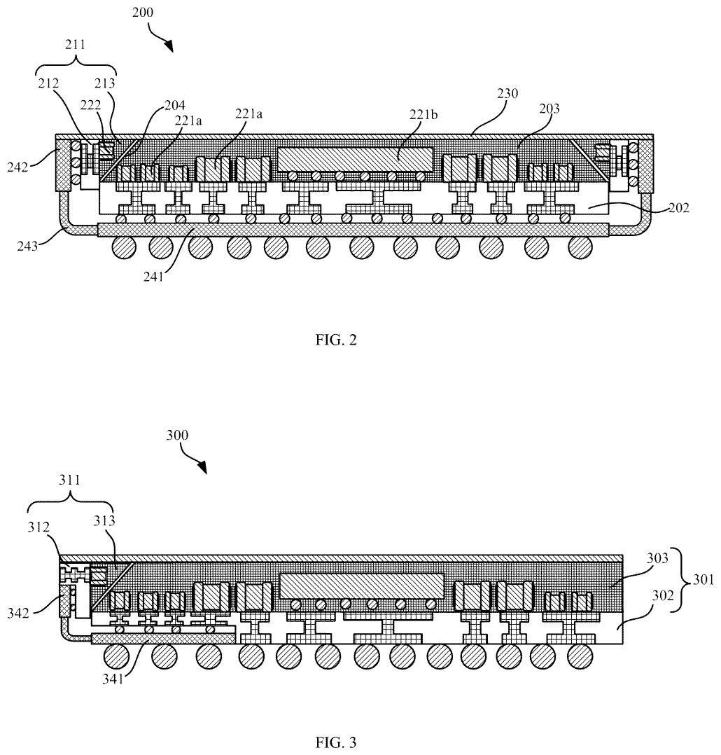

FIG. 2 illustrates a cross-sectional view of an electronic package assembly 200 according to a second embodiment of the present application.

As shown in FIG. 2, the electronic package assembly 200 includes a first electronic package with a first package substrate 202 and a first mold cap 203. The first mold cap 203 has at its periphery two male gaps. The electronic package assembly 200 further includes two second electronic packages 211, each of which has a second package substrate 212 and a second mold cap 213 formed on the second package substrate 212. The second mold cap 213 has at its periphery a female gap which mates one of the male gaps in shape. The first mold cap 203 is connected with the second mold cap 213 through an adhesive material with the male gap of the first mold cap 203 being adjacent to the female gap of the second mold cap 213.

The first electronic package further includes at least one third electronic component 221b mounted on the first package substrate 202. The third electronic component 221b is away from the male gap, i.e., not between the male gap and the first package substrate 202. The first electronic package also includes first electronic components 221a mounted on the first package substrate 202 and between the male gap and the first package substrate 202. Each of the second electronic package 211 further includes a second electronic component 222 mounted on the second package substrate 212 and between the corresponding female gap and the second package substrate 212.

In the embodiment shown in FIG. 2, two first chamfers 204 may be formed at two opposite edges of the first mold cap 203, with a mirrored layout to receive the two second electronic packages 211. The two second electronic packages 211 may be similar as the second electronic package 111 shown in FIG. 1. In some other embodiments, the first mold cap may include multiple first chamfers at different positions of the first mold cap, to accommodate more second electronic packages and more second electronic components, which may further improve the space utilization rate of the electronic package assembly. The chamfers may have the same size or shape, or different sizes or shapes.

Furthermore, as shown in FIG. 2, the electronic package assembly 200 further includes a first linkage substrate 241 which is mounted on a back surface of the first package substrate 202 and away from the first mold cap 203. Also, two second linkage substrates 242 may be mounted on respective back surfaces of the second package substrates 212 and away from the respective second mold caps 213. The second linkage substrates 242 may be both connected with the first linkage substrate 241 via respective flexible links 243, which may have built-in electrical wires for electrically coupling the first linage substrate 241 with the corresponding second linkage substrate 242 or may not have such wires. In this embodiment, the first linkage substrate 241 may be an integrated piece which may be shared by the mirror-arranged second linkage substrates 242. In some other embodiments, each second linkage substrate 242 may be connected to one first linkage substrate 241, and the first linkage substrates 241 may be separated from each other or may be connected together instead of formed as a single piece.

FIG. 3 illustrates a cross-sectional view of an electronic package assembly 300 according to a third embodiment of the present application.

As shown in FIG. 3, the electronic package assembly 300 includes a first electronic package 301 and a second electronic package 311 that are assembled together. A first package substrate 302 of the first electronic package 301 further includes a cavity at its back side for receiving a first linkage substrate 341, such that the first package substrate 302 and the first linkage substrate 341 form together a flat bottom surface of the electronic package assembly 300. Similarly, a second package substrate 312 of the second electronic package 311 further includes a cavity for receiving a second linkage substrate 342, such that the second package substrate 312 and the second linkage substrate 342 form together a flat side surface of the electronic package assembly 300. In this way, the electronic package assembly 300 in both lengthwise direction and widthwise direction of the electronic package assembly 300 can be further reduced in size, and can form a generally regularly shaped structure, i.e., a generally cuboid block. Similar as the electronic package assembly 100 shown in FIG. 1, the first electronic package 301 further includes a first mold cap 303 formed on the first package substrate 302, and the first mold cap 303 has at its periphery a male gap. Also, the second electronic package 311 further includes a second mold cap 313 formed on the second package substrate 312, and the second mold cap 313 has at its periphery a female gap which mates the male gap in shape. The first mold cap 303 is connected with the second mold cap 313 through an adhesive material, while the male gap of the first mold cap 303 is adjacent to the female gap of the second mold cap 313.

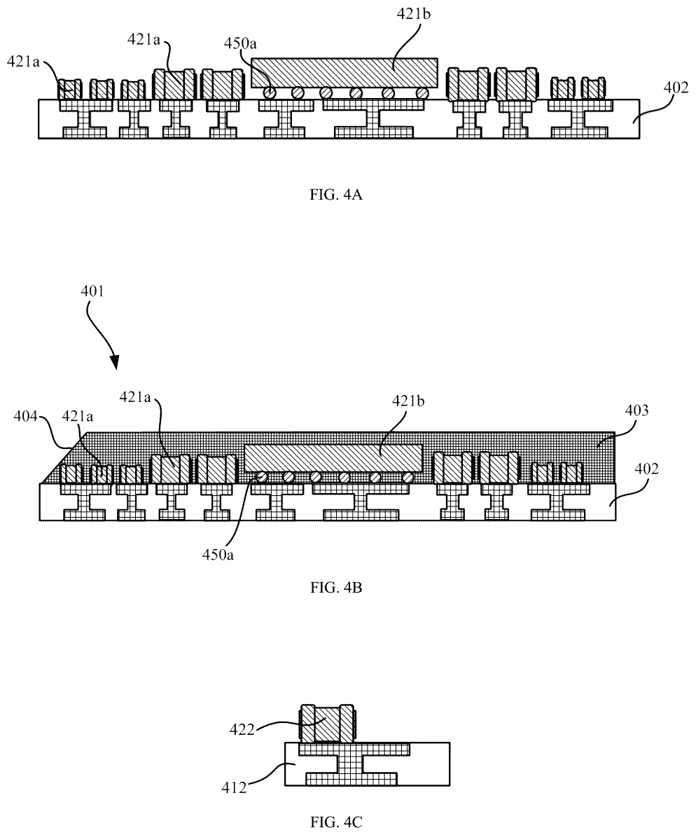

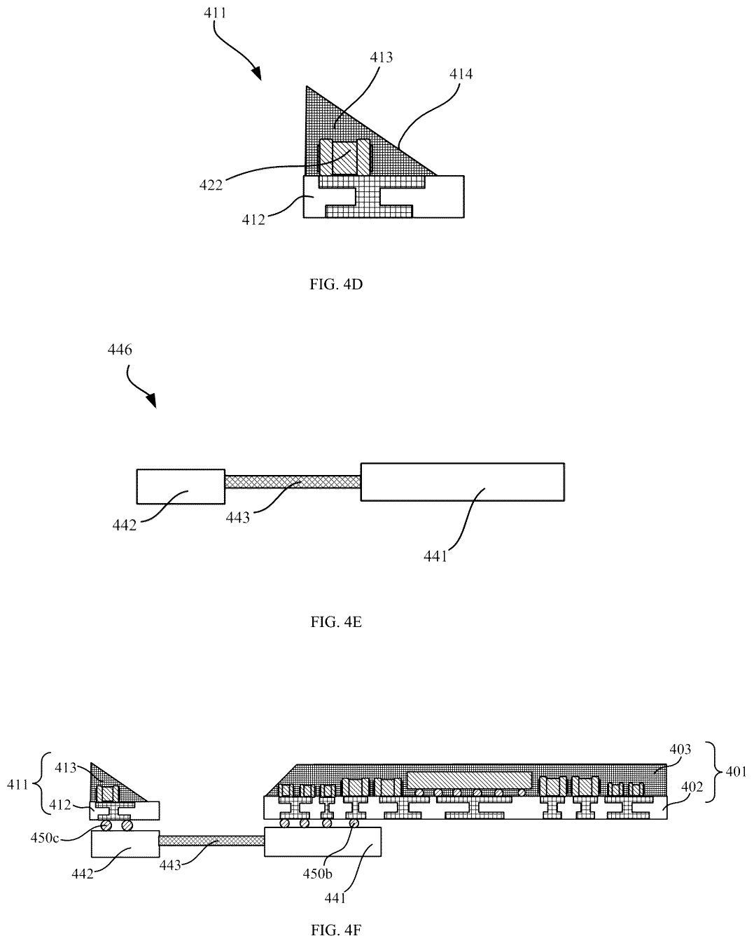

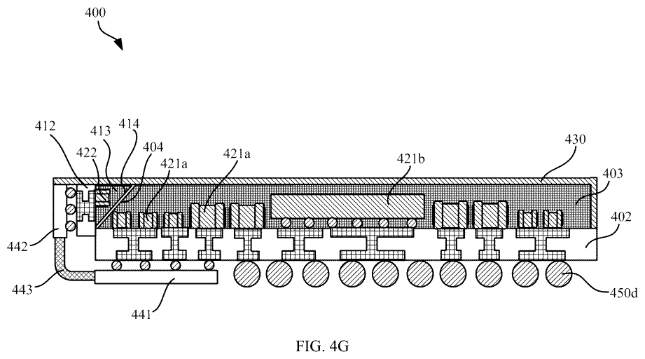

Referring to FIGS. 4A to 4G, various steps of a method for making an electronic package assembly are illustrated according to an embodiment of the present application. For example, the method may be used to make the electronic package assembly 100 shown in FIG. 1. In the following, the method will be described with reference to FIGS. 4A to 4G in more details.

As shown in FIG. 4A, a first package substrate 402 is provided with embedded interconnect wires. A third electronic component 421b is attached onto a front surface of the first package substrate 402. In this example, a plurality of bumps 450a are formed on conductive patterns exposed from the front surface of the first package substrate 402 for attaching the third electronic component 421b on the first package substrate 402. Multiple first electronic components 421a are also mounted onto the front surface of the first package substrate 402, surrounding the third electronic component 421b. The first electronic components 421a have smaller heights than that of the third electronic component 421b. The first electronic components 421a are also electrically connected with the interconnect wires within the first package substrate 402.

Afterwards, as shown in FIG. 4B, a first mold cap 403 is formed on the front surface of the first package substrate 402 using a molding process such as an injection molding process, which covers respective top surfaces of the first electronic components 421a and the third electronic component 421b for encapsulation. Furthermore, at least one of the peripheries of the first mold cap 403 is removed and forms a male gap without the mold material. In some embodiments, the male gap may be formed during the molding process, i.e., using a mold chase may have an internal chamber that has corresponding protrusion. In some other embodiments, the male gap may be formed after the molding process, e.g., using an ablation process or a mechanical sawing process, thereby forming the first electronic package 401. In some embodiment, a first chamfer 404 may be formed at the periphery of the first mold cap 403 to form the male gap. In other embodiments, multiple first chamfers may also be formed at multiple positions of the periphery of the first mold cap. In some embodiments, the first mold cap 403 may undergo a laser marking process to ensure precise positioning of the electronic components encapsulated by the first mold cap 403 in the subsequent processes. As shown in FIG. 4C, a second package substrate 412 is provided with embedded interconnect wires. A second electronic component 422 is mounted onto a front surface of the second package substrate 412. Next, as shown in FIG. 4D, a second mold cap 413 is formed on the front surface of the second package substrate 412 using a molding process, for example, which encapsulates the second electronic component 422. A female gap may be formed at least one position of the periphery of the second mold cap 413 thereby forming the second electronic package 411. The female gap may have a shape and size that is substantially corresponding to that of the male gap of the first mold cap 403. In the embodiment, the female gap may include a second chamfer 414 to match up with the first chamfer 404 of the first mold cap 403.

Next, as shown in FIG. 4E, a linkage assembly 446 is provided. The linkage assembly 446 has a first linkage substrate 441 and a second linkage substrate 442 which are connected with each other via a flexible link 443. As shown in FIG. 4F, the first electronic package 401 is loosely assembled with the second electronic package 411, through the linkage assembly 446. In particular, the first linkage substrate 441 is mounted on a back surface of the first package substrate 402 and away from the first mold cap 403 via conductive bumps 450b; and the second linkage substrate 442 is mounted on a back surface of the second package substrate 412 and away from the second mold cap 413 via conductive bumps 450c.

As shown in FIG. 4G, the male gap of the first mold cap 403 can be placed adjacent to the female gap of the second mold cap 413 by bending the flexible link 443. The first mold cap 403 is then connected with the second mold cap 413 through an adhesive material such that the male gap of the first mold cap 403 is adjacent to the female gap of the second mold cap 413. After connecting the first mold cap 403 with the second mold cap 413 through the adhesive material, the first package substrate 402 can be perpendicular to the second package substrate 412, and at the same time, the first mold cap 403 and the second mold cap 413 form together a flat top surface. Afterwards, a shielding layer 430 may be formed at least on the flat top surface, and optionally on a lateral surface, thereby form the electronic package assembly 400. In some examples, the shielding layer 430 may extend to the structures adjacent to the mold caps, and/or other surfaces (e.g., lateral surfaces) of the mold caps.

While the exemplary electronic package assemblies of the present application are described in conjunction with corresponding figures, it will be understood by those skilled in the art that modifications and adaptations to the electronic package assemblies may be made without departing from the scope of the present invention.

Various embodiments have been described herein with reference to the accompanying drawings. It will, however, be evident that various modifications and changes may be made thereto, and additional embodiments may be implemented, without departing from the broader scope of the invention as set forth in the claims that follow. Further, other embodiments will be apparent to those skilled in the art from consideration of the specification and practice of one or more embodiments of the invention disclosed herein. It is intended, therefore, that this application and the examples herein be considered as exemplary only, with a true scope and spirit of the invention being indicated by the following listing of exemplary claims.

1. An electronic package assembly, comprising:
a first electronic package comprising a first package substrate, and a first mold cap formed on the first package substrate, wherein the first mold cap has at its periphery a male gap; and
a second electronic package comprising a second package substrate, and a second mold cap formed on the second package substrate, wherein the second mold cap has at its periphery a female gap which mates the male gap in shape;
wherein the first mold cap is connected with the second mold cap through an adhesive material with the male gap of the first mold cap being adjacent to the female gap of the second mold cap.

2. The electronic package assembly of claim 1, wherein the male gap comprises a first chamfer, and the female gap comprises a second chamfer.

3. The electronic package assembly of claim 2, wherein the first package substrate is perpendicular to the second package substrate.

4. The electronic package assembly of claim 1, wherein the first electronic package further comprises a first electronic component mounted on the first package substrate and between the male gap and the first package substrate, and the second electronic package further comprises a second electronic component mounted on the second package substrate and between the female gap and the second package substrate.

5. The electronic package assembly of claim 4, wherein the first electronic package further comprises at least one third electronic component mounted on the first package substrate and not between the male gap and the first package substrate, and wherein the at least one third electronic component has a height greater than that of the first electronic component.

6. The electronic package assembly of claim 1, wherein the first mold cap and the second mold cap form together a flat top surface, and the electronic package assembly further comprises a shielding layer formed at least on the flat top surface.

7. The electronic package assembly of claim 1, further comprising a first linkage substrate mounted on the first package substrate and away from the first mold cap, and a second linkage substrate mounted on the second package substrate and away from the second mold cap, wherein the first and second linkage substrates are connected with each other via a flexible link.

8. The electronic package assembly of claim 7, wherein the first package substrate further comprises a cavity for receiving the first linkage substrate, such that the first package substrate and the first linkage substrate form together a flat bottom surface.

9. The electronic package assembly of claim 7, wherein the second package substrate further comprises a cavity for receiving the second linkage substrate, such that the second package substrate and the second linkage substrate form together a flat side surface.

10. The electronic package assembly of claim 7, wherein the first linkage substrate extends across the first package substrate in at least one of a lengthwise direction and a widthwise direction of the first package substrate.

11. A method for forming an electronic package assembly, comprising:
providing a first electronic package comprising a first package substrate, and a first mold cap formed on the first package substrate, wherein the first mold cap has at its periphery a male gap;
providing a second electronic package comprising a second package substrate, and a second mold cap formed on the second package substrate, wherein the second mold cap has at its periphery a female gap which mates the male gap in shape; and
connecting the first mold cap with the second mold cap through an adhesive material such that the male gap of the first mold cap is adjacent to the female gap of the second mold cap.

12. The method of claim 11, wherein the first mold cap and the second mold cap are formed using a molding process.

13. The method of claim 11, before connecting the first mold cap with the second mold cap through an adhesive material, the method further comprising:
providing a linkage assembly having a first linkage substrate and a second linkage substrate which are connected with each other via a flexible link;
mounting the first linkage substrate on the first package substrate and away from the first mold cap; and
mounting the second linkage substrate on the second package substrate and away from the second mold cap.

14. The method of claim 11, wherein the male gap comprises a first chamfer, and the female gap comprises a second chamfer.

15. The method of claim 11, wherein after connecting the first mold cap with the second mold cap through an adhesive material, the first package substrate is perpendicular to the second package substrate.

16. The method of claim 11, wherein the first electronic package further comprises a first electronic component mounted on the first package substrate and between the male gap and the first package substrate, and the second electronic package further comprises a second electronic component mounted on the second package substrate and between the female gap and the second package substrate.

17. The method of claim 16, wherein the first electronic package further comprises at least one third electronic component mounted on the first package substrate and not between the male gap and the first package substrate, and wherein the at least one third electronic component has a height greater than that of the first electronic component.

18. The method of claim 11, wherein after connecting the first mold cap with the second mold cap through an adhesive material, the first mold cap and the second mold cap form together a flat top surface, and wherein the method further comprises:
forming a shielding layer at least on the flat top surface.
